(19) United States
(12) Patent Application Publication
(10) Pub. No.: US 2021/0151617 A1
(43) Pub. Date: May 20, 2021

(54) NIR-REFLECTIVE MULTI-LAYER MATERIAL SHEET

(71) Applicant: DSM IP ASSETS B.V., Heerlen (NL)

(72) Inventors: Yansen LAUW, Echt (NL); Peter Leonardus Elisabeth Maria PASMANS, Echt (NL); Mark Martinus Maria JANSSEN, Echt (NL); Kurt VAN DURME, Echt (NL)

(21) Appl. No.: 17/252,931

(22) PCT Filed: Jul. 8, 2019
(86) PCT No.: PCT/EP2019/068249

§ 371 Date: Dec. 16, 2020

(30) Foreign Application Priority Data
Jul. 10, 2018 (EP) 18182789.0

(51) Int. Cl. H01L 31/049; C08J 5/18; C08J 5/12; C08K 3/22; C08K 3/04; G02B 5/08; H01L 31/048; H01L 31/054; B32B 27/08; B32B 27/20; B32B 27/32

(52) U.S. Cl. CPC H01L 31/049; B32B 2307/402; C08J 5/121; C08K 3/22; C08K 3/04; G02B 5/0816; H01L 31/0481; H01L 31/0549; B32B 27/08; B32B 27/20; B32B 27/32; C08J 2323/06; C08J 2423/06; C08J 2323/12; C08J 2377/00; C08K 2003/2241; B32B 2307/712; B32B 2270/00; B32B 2307/416; C08J 5/18

(57) ABSTRACT

The present invention relates to a multi-layer material sheet comprising an NIR-reflective, translucent polymeric layer having a reflectance of more than 20% of all light with a wavelength from 750 nm to 1000 nm and a transmission of more than 50% of all light with a wavelength from 380 nm to 750 nm and an NIR-reflective, colored polymeric layer having a reflectance of more than 25% of all light with a wavelength from 1000 nm to 2100 nm. The present invention also relates to a backsheet suitable for use in a photovoltaic module, said backsheet comprising said multi-layer material sheet; and to a photovoltaic module comprising said backsheet.

The present invention relates to a near infra-red (NIR) reflective multi-layer material sheet. The invention further relates to a backsheet suitable for a photovoltaic module comprising the NIR-reflective multi-layer material sheet; and to a photovoltaic module comprising said backsheet.

Photovoltaic modules are used for electrical power generation from sunlight and in general consist of a laminate which comprises a solar cell system as the core layer. To form a photovoltaic module, photovoltaic cells grouped in series through appropriate electrical conductors typically using metallic conductors called “ribbons”, are typically encapsulated by an encapsulating material, for example EVA. The encapsulating material enclosing the photovoltaic cells serves as protection against mechanical and weathering-related influences. The core layer is present between a surface layer and a base layer or backsheet, to complete the photovoltaic module. The surface layer, or main surface of the module, typically made of glass, covers the surface of the module exposed to the sun and allows the solar light to reach the cells. The base layer or backsheet carries out a multiplicity of tasks. It guarantees protection of the encapsulating material and the solar cells from environmental influences, while simultaneously preventing the electrical connections from oxidizing. The backsheet may also enhance the power output of the module by reflecting light via the front glass towards the solar cells. Typically, the backsheet prevents moisture, oxygen and other factors depending on the atmospheric conditions from damaging the encapsulating material, the solar cells and the electrical connections. The backsheet also provides for electrical insulation for the photovoltaic cells and the corresponding electrical circuits.

Photovoltaic modules are traditionally mounted outdoors on rooftops or in wide-open spaces where their exposure to sunlight is maximized. When the intensity of sunlight increases, electrical output from photovoltaic modules also increases. However, the efficiency with which a photovoltaic module converts sunlight into electricity is usually approximately 20 percent. The remaining 80 percent of the sunlight is reflected back or absorbed by the module in the form of heat. Energy that is absorbed in the form of heat results in an increase of the operating temperature of the module. Excessive heat decreases the efficiency of the photovoltaic module which converts sunlight into electricity. A typical operating temperature for most photovoltaic modules is around 40-60° C. Many photovoltaic modules lose about 0.3-0.5 percent efficiency for every degree Celsius that their operating temperature increases. A variety of factors may contribute to an increased operating temperature, such as greater ambient air temperature during the day, radiant heat from ground surfaces and other nearby surfaces which may emit heat generated from sun exposure, and increased temperature of the solar module itself from extended sun exposure.

This problem often occurs in situations where photovoltaic modules are integrated in building structures which comprise for example black backsheets for esthetic reasons. While typically rectangular photovoltaic cells in a photovoltaic module are in close proximity, there are usually small gaps between them that expose the underlying backsheet to sunlight. As much as 10 to 15% of the total area covered by a typical monocrystalline silicon photovoltaic module comprising 60 or 72 cells, the backsheet is exposed to direct sunlight.

Where photovoltaic modules are integrated in a building structure, their backsheets are usually colored, especially dark, for example black, to make the photovoltaic modules blend-in with the existing architectural colors and to provide a more homogeneous appearance. The colored, dark, or even black, appearance of the backsheet is usually generated by coating the backsheet with a pigment such as carbon black or iron oxide, or by mixing these pigments with the polymers the backsheet is made of during the manufacturing of the backsheet. Carbon black absorbs basically all light visible to humans. In addition, carbon black also absorbs infrared light, which is electromagnetic radiation with wavelengths longer than that of light generally visible to humans, i.e., with wavelengths ranging from the edge of visible red light at about 750 nm to about 1 mm. The absorption of infrared light will increase the temperature of the backsheet and, ultimately, the operating temperature of the entire photovoltaic module. By contrast to black pigments like carbon black, pigments appearing completely white reflect most, and thus absorb very little, light visible to humans, and they also reflect most of the infrared light. Thus, while dark, or even black, backsheets in photovoltaic modules are desirable for esthetic reasons, such backsheets tend to increase the photovoltaic modules' operating temperature. This reduces the photovoltaic modules' efficiency in converting sun light into electricity. In addition, black backsheets also absorb IR and visible light which further reduces the overall efficiency of the photovoltaic modules.

Photovoltaic module backsheets comprising NIR-reflective pigments are known. For example, US 2013/276876 describes a backsheet for a photovoltaic module comprising a black (low colour reflective) infra-red reflective layer. Optionally this may be backed with a white layer. Further, EP2860764 describes a backsheet having a first (front) layer which is black but transmits NIR and a second (rear) layer which reflects NIR.

However, there remains a need for optimizing the operating temperature and the efficiency of photovoltaic modules comprising the black backsheets.

The object of the present invention is thus to provide an NIR-reflective multi-layer backsheet that lowers absorption of NIR light in the backsheet.

A further object of the present invention is to provide a NIR-reflective multi-layer backsheet that when applied in a PV (photovoltaic) module will increase the module efficiency through increased light absorption in the solar cells and lowering of the operating temperature.

This object has been achieved in providing a multi-layer material sheet is comprising an NIR-reflective, translucent polymeric layer having a reflectance of more than 20% of all light with a wavelength from 750 nm to 1000 nm and a transmission of more than 50% of all light with a wavelength from 380 nm to 750 nm and an NIR-reflective, colored polymeric layer having a reflectance of more than 25% of all light with a wavelength from 1000 nm to 2100 nm. Preferably the NIR-reflective colored polymeric layer has a reflectance of less than 35% of all light with a wavelength from 380 nm to 750 nm.

Generally, electromagnetic radiation is classified according to its wavelength into radio waves, microwaves, infrared light, visible light, ultraviolet light, X-rays and gamma rays. Visible light to the human eye is electromagnetic radiation with a wavelength in the range from about 380 nm to about 750 nm. Near Infrared (NIR) light is electromagnetic radiation with a wavelength longer than that of visible light. Conventionally, near infrared light is considered to have a wavelength in the range from about 750 nm to about 2100 nm. When visible light or infrared light strikes an object, the light can be reflected by the object, go through the object (i.e., be transmitted by the object) or be absorbed by the object. In part, the color a human eye perceives an object to be is determined by the wavelength of the visible light that strikes the object and by the wavelength of the visible light that is reflected by the object into the human eye.

It has surprisingly been found that the reflection of near infrared light can be enhanced by providing a multi-layer material sheet comprising an NIR-reflective, translucent polymeric layer and an NIR-reflective, colored polymeric layer.

In the context of the present invention, translucent means translucent for visible light.

In the context of the present invention, the term colored encompasses black. Accordingly, the term NIR-reflective, colored polymeric layer encompasses an NIR-reflective, black polymeric layer. Colored preferably is black.

As used herein, transmittance is measured by using integrating sphere apparatus according to IS013468-2, at a sample thickness of 100 μm unless specified otherwise.

As used herein, reflectance is measured by using integrating sphere apparatus based on a method according to ISO13468-2, at a sample thickness of 100 μm unless specified otherwise.

The NIR-reflective, translucent polymeric layer is preferably facing the cells and preferably situated on top of the NIR-reflective, colored layer. The benefit of the NIR-reflective, translucent polymeric layer on top of a colored layer is in enhancing the performance of the back sheet providing an increased power output, reduced built-up heat whilst maintaining the colorful appearance of the colored layer. Due to its NIR-reflective property, the introduction of NIR-reflective, translucent polymeric layer increases the total reflected light in the near infra-red (NIR) range (750 nm -1000 nm) which in turn will increase the total power output of the PV cell and reduces the build-up of heat. For example, the relative gain of the PV module, in power output (measured according to IEC 61215) by the introduction of an NIR-reflective, translucent layer on top of a NIR-reflective, black layer in the backsheet compared to a non-NIR-reflective, black layer may be more than 0.2%, more preferably more than 0.5% and even more preferably more than 1.0%. The increase may vary as a function of total loading of pigment and thickness of the NIR-reflective layer, and depends on the design of the photovoltaic module.

The NIR-reflective, translucent polymeric layer and the NIR-reflective, colored polymeric layer may be adjacent to each other. It is also possible that the NIR-reflective, translucent polymeric layer and the NIR-reflective, colored polymeric layer may be separated by an adhesive; in other words, the polymeric layers comprise a connecting or adhesive layer in between. The NIR-reflective translucent polymeric layer is preferably facing the cells. The NIR-reflective, colored polymeric layer is preferably situated in-between the NIR-reflective, translucent polymeric layer and an outside layer of the backsheet.

The NIR-reflective, translucent polymeric layer preferably comprises an inorganic near infrared-reflective pigment or inorganic near infrared-reflective pigments. The inorganic near infrared-reflective pigments are selected from the group consisting of mica, SiO₂, TiO₂, tin oxide (SnO or SnO₂), ZnO, ZnSnO, aluminium-doped ZnO, indiumtinoxide, antimonytinoxide, ZrO₂, iron oxide black Fe₃O₄ (magnetite), chromium oxide green Cr₂O₃ or chromium iron brown (Fe,Cr)₂O₃ and mixtures thereof. Preferably, the inorganic near infrared-reflective pigment is selected from the group consisting of mica, SiO₂, TiO₂, tin oxide (SnO or SnO₂), ZnO, ZnSnO, aluminium-doped ZnO, indiumtinoxide, antimonytinoxide, ZrO₂ and mixtures thereof. More preferably the NIR-reflective, translucent polymeric layer comprises an NIR reflecting pigment selected from mica and SiO₂. A commercially known composition comprising suitable pigments is Iriotec®, for example Iriotec ® 9870. Iriotec® 9870 comprises mica+SiO₂, TiO₂ (rutile), SnO₂ and ZrO₂. The NIR-reflective, translucent polymeric layer may comprise from 0.1 wt. % to 8 wt. % of the inorganic NIR-reflective pigment based on the total weight of the NIR-reflective, translucent polymeric layer. More preferably the NIR-reflective, translucent polymeric layer comprises from 0.15 wt. % to 6 wt. % of the inorganic NIR-reflective pigment. Still more preferably the NIR-reflective, translucent polymeric layer comprises from 0.2 wt. % to 4 wt. % of the inorganic NIR-reflective pigment.

The NIR-reflective, translucent polymeric layer according to the present invention is preferably a thin film layer; preferably with a thickness of less than 300 μm; which is transparent to visible light with a total (regular & diffuse) transmittance ≥50%, as measured by using integrating sphere apparatus according to ISO13468-2. Preferably, the thickness is from 5 to 200 μm; more preferably from 10 to 150 μm; more preferably from 20 to 100 μm; most preferably 30 to 80 μm. Preferably, total transmittance is at least 60%; more preferably at least 70%, for example at least 80%, or even at least 90%.

Typically, the reflectance of the NIR-reflective, translucent polymeric layer for light having a wavelength from 750 nm to 1000 nm is more than 30%; preferably more than 40%; more preferably more than 50%; or even more than 60%.

The NIR-reflective, translucent polymeric layer preferably comprises a thermoplastic polymer. The thermoplastic polymer is typically selected from the group consisting of a polyolefin, a mixture of polyolefins, a TPO or a blend from a polyolefin and a semi-crystalline polymer. The thermoplastic polymer is preferably a polyolefin or a mixture of polyolefins. The polyolefin is preferably selected from the group consisting of optionally functionalized polyethylene homo or copolymers, optionally functionalized polypropylene homo or (block-)copolymers, cyclic olefin copolymers, polymethylpentene, a thermoplastic polyolefine (TPO) or blends thereof.

A thermoplastic polyolefin (TPO) as described herein means for example PP/EPR reactor blends resins (such as Hifax CA 10, Hifax CA 12, Hifax CA 02, Hifax CA 60, supplied by Basell) or elastomeric polypropylene (PP) resins (known under the trade name Versify 2300.01 or 2400.01 in mixture with e.g. random PP copolymers) or thermoplastic vulcanisates (known under the trade name Santoprene)

Examples of functionalized polyethylene or polypropylene homo-or (block-)copolymers are for example ethylene or propylene copolymerized with polar co-monomers chosen from maleic acid anhydride, vinyl acetate, acrylic and methacrylic ester such as methylacrylate, ethylacrylate, butylacrylate or ethylhexylacrylate. Preferably, ethylene is co-polymerised with methylacrylate.

Preferably the NIR-reflective, translucent polymeric layer comprises a functionalized polyethylene, polyethylene and optionally polypropylene.

The NIR-reflective, colored polymeric layer comprises a polymeric material and at least one NIR-reflective pigment. The layer is also colored. Accordingly, it typically comprises a colored pigment. The NIR-reflective pigment and the colored pigment may the same. The NIR-reflective, colored polymeric layer preferably comprises a polymeric material and at least one NIR-reflective, colored pigment.

The NIR-reflective, colored polymeric layer according to the present invention typically has a thickness of from 50 to 600 μm; more preferably from 100 to 400 μm; most preferably from 200 to 300 μm.

The NIR-reflective, colored polymeric layer according to the present invention typically has a reflectance of more than 40% of all light with a wavelength of 1000 nm to 2100 nm. More preferably reflectance is more than 50%, more than 60% or even more than 70% of all light with a wavelength of 1000 nm to 2100 nm. The NIR-reflective, colored polymeric layer according to the present invention typically has a reflectance of more than 40% of all light with a wavelength of 1200 nm to 1600 nm. More preferably reflectance is more than 50%, more than 60%, more than 70% or even more than 80% of all light with a wavelength of 1200 nm to 1600 nm.

The polymeric material of the NIR-reflective, colored polymeric layer is preferably a thermoplastic polymer. The thermoplastic polymer is selected from the group consisting of a polyolefin, a functionalized polyolefine, polyester, polyamide, rubber modified polyesters, PMMA, PEEK, polycarbonate, polyether sulfone, polyoxymethylene, polyimide, polyphenylene sulfide or polyphenylene oxide. Preferably, the thermoplastic polymer of the NIR-reflective, colored polymeric layer is selected from the group consisting of polyamide, polyester, rubber modified polyester, polyolefin and combinations thereof. Examples of polyolefins are polyethylene or polypropylene homo-or (block-)copolymers. Preferably the polyolefin is polypropylene.

Examples of functionalized polyolefins are functionalized polyethylene or polypropylene homo-or (block-)copolymers, for example ethylene or propylene copolymerized with polar co-monomers chosen from maleic acid anhydride, vinyl acetate, acrylic and methacrylic ester such as methylacrylate, ethylacrylate, butylacrylate or ethylhexylacrylate. Preferably, the functionalized polyolefin is propylene co-polymerized with maleic acid anhydride.

Examples of polyesters include poly(trans-1,4-cyclohexylene alkane dicarboxylates such as poly(trans-1,4-cyclohexylene succinate) and poly(trans-1,4-cyclohexylene adipate), poly(cis or trans-1,4-cyclohexanedimethylene), alkanedicarboxylates such as poly(cis 1,4-cyclohexanedimethylene)oxalate and poly(cis 1,4-cyclohexanedimethylene)succinate, poly(alkylene terephthalates) such as polyethyleneterephthalate and polytetramethyleneterephthalate, poly(alkylene isophthalates such as polyethyleneisophthalate and polytetramethyleneisophthalate, poly(p-phenylene alkanedicarboxylates such as poly(p-phenylene glutarate) and poly(p-phenylene adipate), poly(p-xylene oxalate), poly(o-xylene oxalate), poly(p-phenylenedialkylene terephthalates) such as poly(p-phenylenedimethylene terephthalate) and poly(p-phenylene-di-1,4-butylene terephthalate, poly(alkylene-1,2-ethylenedioxy-4,4′-dibenzoates) such as poly(ethylene-1,2-ethylenedioxy-4,4′-dibenzoates), poly(tetramethylene-1,2-ethylenedioxy-4,4′-dibenzoate) and poly(hexamethylene-1,2-ethylenedioxy-4,4′-dibenzoate), poly(alkylene-4,4′-dibenzoates) such as poly(pentamethylene-4,4′-dibenzoate), poly(hexamethylene-4,4′-dibenzoate and poly(decannethylene-4,4′-dibenzoate), poly(alkylene-2,6-naphthalene dicarboxylates) such as poly(ethylene-2,6-naphthalene dicarboxylates), poly(trimethylene-2,6-naphthalene dicarboxylates) and poly(tetramethylene-2,6-naphthalene dicarboxylates), and poly(alkylene sulfonyl-4,4′-dibenzoates) such as poly(octamethylene sulfonyl-4,4′-dibenzoate) and poly-(decamethylene sulfonyl-4,4′-dibenzoate. Preferred polyesters are poly(alkylene terephthalates) such as polyethylene terephthalate (PET) or polybutylene terephthalate (PBT).

The polyester may be impact modified by an elastomer that contains functional groups that bond chemically and/or interact physically with the polyester. The functional groups are chosen from the group consisting of anhydrides, acids, epoxides, silanes, isocyanates, oxazolines, thiols and/or (meth)acrylates. Preferably the functional groups are epoxides.

The elastomer as mentioned herein means an elastomer chosen from the group consisting of EPDM, SBS, SEBS, ethylene-propylene elastomers such as EPDM, styrene-butadiene elastomers such as SBS or SEBS. The amount of functional groups that bond chemically and/or interact physically with the polyester is preferably from 0.01 to 5 wt. %. (based on the total weight of the impact modified polyester).

Examples of polyamides are polyamide 6, polyamide 6,6; polyamide 4,6; polyamide 6,10; polyamide 6,12; polyamide 6,14; polyamide 6,13; polyamide 6,15; polyamide 6,16; polyamide 11;, polyamide 12, polyamide 10, polyamide 9,12, polyamide 9,13, polyamide 9,14, polyamide 9,15, polyamide 6,16, polyamide 10,10, polyamide 10,12, polyamide 10,13, polyamide 10,14, polyamide 12,10, polyamide 12,12, polyamide 12,13, polyamide 12,14, adipic adipamide/terephthalic adipamide copolyamide, terephthalic adipamide/isophthalic adipamide copolyamide, poly(adipic acid meta-dimethylbenzamide), terephthalic adipamide/terephthalic 2-methylglutaramide, adipic adipamide/terephthalic adipamide/isophthalic adipamide copolyamide and polycaprolactam-terephthalic adipamide.

Preferably the NIR-reflective, colored polymeric layer comprises polypropylene or propylene co-polymerized with maleic acid anhydride.

Examples of NIR-reflective, colored pigments are given in below table 1.

TABLE 1

| Color | Color subfamily | Paint name | Pigment name |
|---|---|---|---|
| White | Titanium dioxide white | Titanium dioxide white | Titanium Dioxide (PW 6) |
| Black | Chromium iron oxide | Chromium Green-Black | Shepherd Black 10C909 (PG 17) |
| | selective black | Hematite | |
| | Chromium iron oxide | Chromium Green-Black | Ferro Black V-797 |
| | selective black | Hematite Modified | |
| | Chromium iron oxide | Chromium Green-Black | Ferro Black V-799 |
| | selective black | Hematite Modified | |
| | | Chromium-free Black | Ferro Eclipse Black V-10202 |
| | Chromium iron oxide | Chromium Iron Oxide | Shepherd Black 411 (PBr 29) |
| | selective black | | |
| | | Chromium Iron Oxide | Shepherd Black 10C912 |
| | | Chromium Iron Oxide | Shepherd Black 10G996 |
| | | Chromium Iron Oxide | Shepherd Black 10P922 |
| | | Chromium Iron Oxide | Shepherd Black 10P923 |
| | | Chromium Iron Oxide | Shepherd Black 10P950 |
| | | Chromium Iron Oxide | Shepherd Black 30C940 |
| | | Chromium Iron Oxide | Shepherd Black 30C941 |
| | | Chromium Iron Oxide | BASF Sicopal Black K 0095 |
| | | Manganese Chromium | BASF Meteor Plus 9880/9889 |
| | | Iron Oxide | |
| | Organic selective black | Perylene black | BASF Paliogen Black |
| | | | L0086 (PB 32) |
| Brown | Iron oxide brown | Burnt Sienna | Calcined Natural |
| | Iron oxide brown | Raw Sienna | Iron Oxide (PBr 7) |
| | Iron oxide brown | Raw Umber | Natural Iron Oxide (PBr 7) |
| | Other brown | Iron Titanium Brown | Natural Iron Oxide |
| | Other brown | Spinel | w/Manganese (PBr 7) |
| | Other brown | Iron Titanium Brown | Shepherd Brown 156 (PBk 12) |
| | Other brown | Spinel | Shepherd Brown 8 (PBk 12) |
| | Other brown | Iron Titanium Brown | Shepherd Golden Brown 19 |
| | Other brown | Spinel | (PBk 12) |
| | | Manganese Antimony | Ferro Chestnut Brown V-10364 |
| | | Titanium Buff Rutile | (PY 164) |
| | | Zinc Iron Chromite Brown | Shepherd Brown 12 (PBr 33) |
| | | Spinel | Shepherd Brown 157 (PBr 33) |
| | | Zinc Iron Chromite Brown | |
| | | Spinel | |
| Green | Chromium oxide green | Chrome Green | Bayer GN-M Chrome Oxide |
| | | | Green (PG 17) |
| | Chromium oxide green | Chromium Oxide Green | Anhydrous Chromium |
| | | | Sesquioxide (PG 17) |
| | Modified chromium oxide | Chromium Green-Black | Ferro Camouflage Green |
| | green | Modified | V-12650 |
| | | Chromium Green-Black | Ferro Eclipse Green V-10241 |
| | | Hematite | |
| | Cobalt titanate green | Cobalt Teal | Light Green Oxide (PG 50) |
| | Cobalt titanate green | Cobalt Titanate Green | Shepherd Green 223 (PG 50) |
| | | Spinel | |
| | Cobalt titanate green | Cobalt Titanate Green | Shepherd Sherwood Green 5 |
| | | Spinel | (PG 50) |
| | Phthalocyanine green | Phthalo Green | Chlorinated Copper |
| | | | Phthalocyanine (PG 7) |
| | Phthalocyanine green | Phthalo Green | Clariant GT-674-D Endurophthal |
| | | | Green B (PG 7) |
| Yellow | Cadmium yellow | Cadmium Yellow Light | Cadmium Yellow (PY 35) |
| | Chrome yellow | Chrome Yellow | Dominion Color Krolor KY-781-D |
| | | | (PY 34) |
| | Chrome titanate yellow | Chrome Antimony | Ferro Autumn Gold V-10415 |
| | | Titanium Buff Rutile | (PBr 24) |
| | Chrome titanate yellow | Chrome Antimony | Ferro Bright Golden Yellow |
| | | Titanium Buff Rutile | V-10411 (PBr 24) |
| | Chrome titanate yellow | Chrome Antimony | Shepherd Yellow 193 (PBr 24) |
| | | Titanium Buff Rutile | |
| | Chrome titanate yellow | Chrome Titanate Yellow | Ishihara Tipaque TY-300 |
| | | | (PBr 24) |
| | Nickel titanate yellow | Nickel Antimony Titanium | Ferro Yellow V-9415 (PY 42) |
| | | Yellow Rutile | |
| | Nickel titanate yellow | Nickel Antimony Titanium | Ferro Yellow V-9416 (PY 53) |
| | | Yellow Rutile | |
| | Nickel titanate yellow | Nickel Antimony Titanium | Shepherd Yellow 195 (PY 53) |
| | | Yellow Rutile | |
| | Nickel titanate yellow | Nickel titanate yellow | Ishihara Tipaque TY-50 (PY 53) |
| | Strontium Chromate | Primer | Strontium Chromate Yellow + |
| | Yellow + Titanium Dioxide | | Titanium Dioxide |

Preferred NIR-reflective, colored pigments, for a dark colored layer are chromium iron oxide like Sicopal Black K0095 from BASF or Shepherd black 10G996 from Shepherd. The NIR-reflective, colored polymeric layer may comprise from 0.1 wt. % to 8 wt. % of the NIR-reflective, colored pigment based on the total weight of the NIR-reflective, colored polymeric layer. More preferably the NIR-reflective, colored polymeric layer comprises from 0.15 wt. % to 6 wt. % of the NIR-reflective, colored pigment. Still more preferably the NIR-reflective, colored polymeric layer comprises from 0.2 wt. % to 4 wt. % of the NIR-reflective, colored pigment.

The multi-layer material sheet of the present invention may further comprise other polymeric layers such as one or more adhesive layers, a structural reinforcement layer and/or a weather-resistant layer. Preferably it comprises a weather-resistant layer.

The weather-resistant layer may comprise a polyamide, PTFE, a polyolefin or a polyester. Examples of suitable polyolefins, polyesters or polyamides are as described earlier. Preferably the weather-resistant layer comprises polyamide 12. Alternatively, the weather-resistant layer comprises polypropylene.

The weather-resistant layer may further comprise inorganic fillers such as calcium carbonate, titanium dioxide, barium sulfate, mica, talc, kaolin, glass microbeads and glass fibers or additives such as UV stabilizers, heat stabilizers or anti-oxidants. More preferably the weather-resistant layer may be colored by any of the colored (including black) pigments (including IR-reflective, colored pigments) as indicated earlier, or by a white pigment. Most preferably the weather-resistant layer comprises a white pigment.

In one embodiment the adhesive layer is the NIR-reflective colored polymeric layer as defined in the present invention.

In another embodiment the structural layer is the NIR-reflective colored polymeric layer as defined in the present invention.

In one embodiment the multi-layer material sheet comprises the following layers:
a) NIR-reflective, translucent polymeric layer facing the cells
b) an adhesive polymeric layer comprising an NIR-reflective pigment of a particular color including dark color
c) a structural polymeric layer
d) an adhesive polymeric layer which can be the same or different than layer (b)
e) an air-side facing polymeric layer or weather-resistant layer

In this embodiment the layers a) and b) comprise the ingredients as indicated earlier. This means that the adhesive layer is the NIR-reflective, colored polymeric layer as described earlier.

The structural layer c) for example comprises a thermoplastic polymer such as polyolefin or a mixture of polyolefin, for example a polypropylene or a mixture of polypropylene, a polyester, for example PET or PBT optionally rubber modified or a polyamide. Optionally the structural layer may comprise an NIR-reflective, colored pigment, for example chromium iron oxide, more specifically Sicopal Black K0095 from BasF or Shepherd black 10G996 from Shepherd.

The polyester such as PET or PBT may be impact modified by an elastomer that contains functional groups that bond chemically and/or interact physically with the polyester. The functional groups are chosen from the group consisting of anhydrides, acids, epoxides, silanes, isocyanates, oxazolines, thiols and/or (meth)acrylates. Preferably the functional groups are epoxides.

The elastomer as mentioned herein means an elastomer chosen from the group consisting of EPDM, SBS, SEBS, ethylene-propylene elastomers such as EPDM, styrene-butadiene elastomers such as SBS or SEBS. The amount of functional groups that bond chemically and/or interact physically with the polyester is preferably from 0.01 to 5 wt. % (based on the total weight of the impact modified polyester).

Examples of polyamides are polyamide 6, polyamide 6,6, polyamide 4,6, polyamide 6,10, polyamide 6,12, polyamide 6,14, polyamide 6,13, polyamide 6,15, polyamide 6,16, polyamide 11, polyamide 12, polyamide 10, polyamide 9,12, polyamide 9,13, polyamide 9,14, polyamide 9,15, polyamide 6,16, polyamide 10,10, polyamide 10,12, polyamide 10,13, polyamide 10,14, polyamide 12,10, polyamide 12,12, polyamide 12,13, polyamide 12,14, adipic adipamide/terephthalic adipamide copolyamide, terephthalic adipamide/isophthalic adipamide copolyamide, poly(adipic acid meta-dimethylbenzamide), terephthalic adipamide/terephthalic 2-methylglutaramide, adipic adipamide/terephthalic adipamide/isophthalic adipamide copolyamide and polycaprolactam-terephthalic adipamide.

The air-side facing polymeric layer or weather-resistant layer e) situated at the outside of the backsheet may comprise a polyamide, PTFE, a polyolefine or a polyester. Examples of polyolefins, polyesters or polyamides are as described earlier. Preferably the weather-resistant layer e) comprises polyamide 12. Alternatively the weather-resistant layer comprises a polyolefin, for example polypropylene.

The weather-resistant layer e) may further comprise inorganic fillers such as calcium carbonate, titanium dioxide, barium sulfate, mica, talc, kaolin, glass microbeads and glass fibers or additives such as UV stabilizers, heat stabilizers or anti-oxidants. More preferably the weather-resistant layer may be colored by any of the NIR-reflective pigments as indicated earlier, or by a white pigment. Most preferably the weather-resistant layer e) comprises a white pigment.

In a further embodiment the multi-layer backsheet may comprise the following layers:
a) NIR-reflective, translucent polymeric layer facing the cells
b) an adhesive polymeric layer comprising an NIR-reflective pigment of a particular color including dark color
c) a structural polymeric layer comprising a NIR-reflective pigment of a particular color including dark color
d) an adhesive polymeric layer which can be the same or different than layer (b)
e) an air-side facing polymeric layer or weather-resistant layer. In this embodiment it is possible that both adhesive layers comprise comprise a NIR-reflective pigment of a particular color including dark color. The layers a)-e) comprise the ingredients as described earlier.

In another embodiment the multi-layer backsheet may comprise the following layers:
a) NIR-reflective translucent polymeric layer facing the cells comprising a NIR-reflective pigment chosen from the group consisting of mica, SiO₂, TiO₂, tinoxide, ZnO, ZnSnO, aluminium-doped ZnO, indiumtinoxide, antimonytinoxide, ZrO₂ or mixtures thereof.
b) an adhesive polymeric layer comprising a NIR-reflective pigment chosen from the group consisting of mica, SiO₂, TiO₂, tin oxide, ZnO, ZnSnO, aluminium-doped ZnO, indiumtinoxide, antimonytinoxide, ZrO₂ or mixtures thereof, Chromium iron oxide like Sicopal Black K0095 from BASF or Shepherd black 10G996 from Shepherd
c) a structural polymeric layer comprising a NIR-reflective pigment chosen from Chromium iron oxide like Sicopal Black K0095 from BASF or Shepherd black 10G996 from Shepherd
d) an adhesive polymeric layer which can be the same or different than layer (b)
e) an air-side facing polymeric layer or weather-resistant layer, preferably comprising a white pigment.
   In this embodiment the layers a)-e) comprise the ingredients as described earlier.

The polymeric layers in may further comprise additives known in the art. Preferably the polymeric layers comprise at least one additive selected from UV stabilizers, UV absorbers, anti-oxidants, thermal stabilizers and/or hydrolysis stabilizers. When such additives stabilizers are present, a polymeric layer may comprise from 0.05 to 10 wt. % additives more preferably from 1 to 5 wt. % additives, based on the total weight of the polymer.

White pigments such as talc, mica, TiO₂, ZnO or ZnS may also be added.

In a further embodiment the multi-layer backsheet may comprise the following layers:
a) NIR-reflective translucent polymeric layer facing the cells comprising a NIR-reflective pigment chosen from the group consisting of mica, SiO₂, TiO₂, tinoxide, ZnO, ZnSnO, aluminium-doped ZnO, indiumtinoxide, antimonytinoxide, ZrO₂ or mixtures thereof
b) an adhesive polymeric layer comprising a NIR-reflective pigment chosen from chromium iron oxide like Sicopal Black K0095 from BASF or Shepherd black 10G996 from Shepherd
c) a structural polymeric layer comprising a NIR-reflective pigment chosen from chromium iron oxide like Sicopal Black K0095 from BASF or Shepherd black 10G996 from Shepherd
d) an adhesive polymeric layer which can be the same or different than layer (b)
e) an air-side facing polymeric layer or weather-resistant layer, preferably comprising a white pigment
   In this embodiment the layers a)-e) comprise the polymeric materials and possible additives as described earlier.

In one embodiment, the present invention provides a multi-layer material sheet comprising:

a) an NIR-reflective, translucent polymeric layer, which layer comprises functionalized polyethylene, polyethylene and optionally polypropylene and an NIR-reflective pigment;

b) an NIR-reflective, colored layer, which layer comprises a polyolefin, an NIR reflective pigment and a colored pigment; and c) a weather-resistant layer.

Typically, the multi-layer material sheet further comprises a weather-resistant layer (c), which layer comprises a polyolefin or a polyamide. Polyolefin and polyamide is as defined herein.

Typically, the NIR-reflective, translucent polymeric layer comprises ethylene copolymerized with methacrylate. Typically, the NIR-reflective pigment of the NIR-reflective, translucent polymeric layer (a) comprises mica, SiO₂ or both. Typically, the amount of NIR-reflective pigment of the NIR-reflective, translucent polymeric layer (a) is from 0.1 to 8 wt. % based on the total weight of the NIR-reflective, translucent polymeric layer. Typically, the NIR-reflective, translucent polymeric layer (a) has a thickness of from 10 to 150 μm.

Typically, the NIR-reflective, colored layer comprises polypropylene or propylene copolymerized with maleic anhydride. Typically, in the NIR-reflective, colored layer (b) the NIR-reflective pigment is also the colored pigment. Typically, in the NIR-reflective, colored layer (b) the NIR-reflective pigment is present in an amount of from 0.1 to 8 wt. % based on the total weight of the layer. Typically, the NIR-reflective, colored layer (b) has a thickness of from 100 to 400 μm. Typically, the color is black.

Typically, the weather-resistant layer comprises polyamide 12 or polypropylene. Typically, the weather resistant layer has a thickness of from 10 to 50 μm. Typically, the weather-resistant layer comprises a white pigment.

A particular preferred embodiment is a multi-layer material sheet as described above, wherein:

a) the NIR-reflective, translucent polymeric layer has a thickness of from 10 to 150 μm, comprises ethylene copolymerized with methacrylate, and from 0.1 to 8 wt. % of an NIR-reflective pigment comprising mica and SiO₂;

b) the NIR-reflective, colored layer (b) has a thickness of from 100 to 400 μm, comprises polypropylene or propylene copolymerized with maleic anhydride, and from 0.1 to 8 wt. % of NIR-reflective pigment which is also a colored pigment; and

c) the weathering layer comprises polyamide 12 or polypropylene.

The multi-layer material sheet according to the present invention may be prepared using a multi-layer fusion or co-extrusion process. The process comprises the following steps: compounding of the individual formulations of the different layers including inorganic fillers, additives and stabilizers followed by extrusion of the different layers and laminating them.

Alternatively, the multi-layer material sheet according to the present invention may also be manufactured by: (1) pelletizing the materials of the different layers in an extruder to obtain particles or pellets of the different layers and (2) fusing and co-extruding the pellets or particles, prepared in step (1) through the extruder. Alternatively, it is possible that the multi-layer material sheet is obtained by melt co-extruding of the different layers in the multi-layer material sheet via the following steps: (1) preparing the polymer compositions of the different layers by separately mixing the components of the different layers, (2) melting of the different polymer compositions to obtain different melt streams, (3) combining the melt streams by co-extrusion in one extrusion die, (4) cooling the co-extruded layer.

The present invention further provides a backsheet suitable for a photovoltaic module, said backsheet comprising a multi-layer materal sheet as defined herein. The multi-layer material sheet is typically suitable for use as a backsheet in a photovoltaic module. Typically, the multi-layer material sheet is simply cut to size to produce a backsheet. Accordingly, preferably, the multi-layer material sheet is a backsheet suitable for a photovoltaic module.

When used as a backsheet, the NIR-reflective, translucent layer is oriented towards the front, i.e. towards the solar cells, and the NIR-reflective, colored layer is oriented towards the back, i.e. away from the solar cells.

The present invention further relates to a photovoltaic module comprising the multi-layer material sheet (or backsheet) according to the present invention. The photovoltaic module comprises at least the following layers in order of position from the front sun-facing side to the back non-sun-facing side: (1) a transparent front sheet, (2) optionally a front encapsulant layer, (3) a solar cell layer, (4) optionally a back encapsulant layer, and (5) the multi-layer backsheet according to the present invention, representing the rear protective layer of the PV module.

The front sheet is typically a glass plate.

The front and back encapsulant are designed to encapsulate and protect the fragile solar cells. The “front side” corresponds to a side of the photovoltaic cell irradiated with light, i.e. the light-receiving side, whereas the term “backside” corresponds to the reverse side of the light-receiving side of the photovoltaic cells. Suitable encapsulants typically possess a combination of characteristics such as high impact resistance, high penetration resistance, good ultraviolet (UV) light resistance, good long term thermal stability, adequate adhesion strength to glass and/or other rigid polymeric sheets, high moisture resistance, and good long-term weather ability. Examples of encapsulants are ionomers, ethylene vinyl acetate (EVA), poly(vinyl acetal), polyvinylbutyral (PVB), thermoplastic polyurethane (TPU), polyvinylchloride (PVC), metallocene-catalyzed linear low density polyethylenes, polyolefin block elastomers, poly(ethylene-co-methyl acrylate) and poly(ethylene-co-butyl acrylate), silicone elastomers or epoxy resins. EVA is the most commonly used encapsulant material. EVA sheets are usually inserted between the solar cells and the top surface (called front encapsulant) and between the solar cells and the rear surface (called a back encapsulant).

The solar cells in the solar cell layer may be any kind of solar cells, such as thin-film solar cells (for example copper indium gallium selenide solar cells and cadmium telluride solar cells) and wafer-based solar cells.

The present invention further relates to a multi-layer backsheet for a photovoltaic module comprising a NIR reflective translucent polymeric layer having a reflectance of more than 20% of all light with a wavelength from 750 nm to 1000 nm and a transmission of more than 50% of all light with a wavelength from 380 nm to 750 nm and a colored polymeric layer having a reflectance of less than 35% of all light with a wavelength from 380 nm to 2100 nm. Preferably the colored polymeric layer comprises carbon black. The NIR reflective translucent polymeric layer and the colored polymeric layer are composed of the materials as described earlier. The multi-layer material sheet may also further comprise at least an adhesive layer, a structural layer and a weather-resistant layer.

Typically, the colored polymeric layer has a reflectance of less than 30% of all light with a wavelength from 380 nm to 2100 nm; more preferably less than 25%; still more preferably less than 20%.

Typically, total transmittance of the NIR-reflective, translucent polymeric layer of all light with a wavelength from 380 nm to 750 nm is at least 60%, preferably at least 70%; more preferably at least 80%, for example at least 90%.

Typically, the reflectance of the NIR-reflective, translucent polymeric layer for light having a wavelength from 750 nm to 1000 nm is more than 30%; preferably more than 40%; more preferably more than 50%; or even more than 60%.

In a preferred embodiment the multi-layer backsheet comprises the following layers:
a) NIR-reflective translucent polymeric layer facing the cells comprising a NIR-reflective pigment chosen from the group consisting of mica, SiO₂, TiO₂, tinoxide, ZnO, ZnSnO, aluminium-doped ZnO, indiumtinoxide, antimonytinoxide, ZrO₂ or mixtures thereof
b) an adhesive polymeric layer comprising a NIR-reflective pigment chosen from the group consisting of mica, SiO₂, TiO₂, tinoxide, ZnO, ZnSnO, aluminium-doped ZnO, indiumtinoxide, antimonytinoxide, ZrO₂ or mixtures thereof, chromium iron oxide like Sicopal Black K0095 from BASF or Shepherd black 10G996 from Shepherd
c) a structural polymeric layer comprising carbon black
d) an adhesive polymeric layer which can be the same or different than layer (b)
e) an air-side facing polymeric layer or weather-resistant layer, preferably comprising a white pigment

In an even more preferred embodiment the multi-layer backsheet comprises the following layers;
a) NIR-reflective translucent polymeric layer facing the cells comprising an NIR-reflective pigment chosen from the group consisting of mica, SiO₂, TiO₂, tin oxide, ZnO, ZnSnO, aluminium-doped ZnO, indiumtinoxide, antimonytinoxide, ZrO₂ or mixtures thereof
b) an adhesive polymeric layer without pigment
c) a structural polymeric layer comprising carbon black
d) an adhesive polymeric layer which can be the same or different than layer (b)
e) an air-side facing polymeric layer or weather-resistant layer, preferably comprising a white pigment

The different layers in these embodiments are preferably composed of the polymeric materials and additives as described earlier.

The invention will be further explained with the help of figures and examples without being however limited thereto.

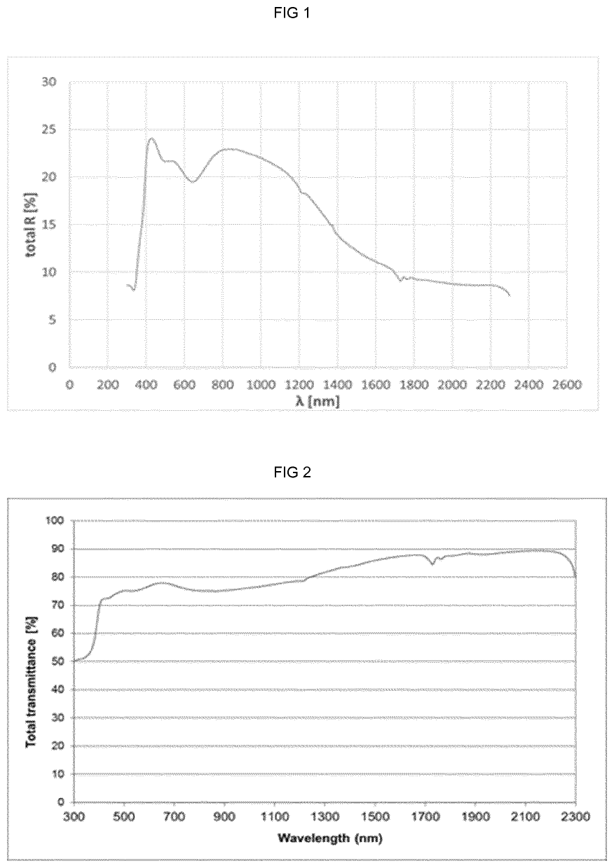

FIG. 1 is a plot of reflectivity against wavelength for the film of Example 3, an NIR-reflective, translucent polymeric layer.

FIG. 2 is a plot of transmittance against wavelength for the film of Example 3, an NIR-reflective, translucent polymeric layer.

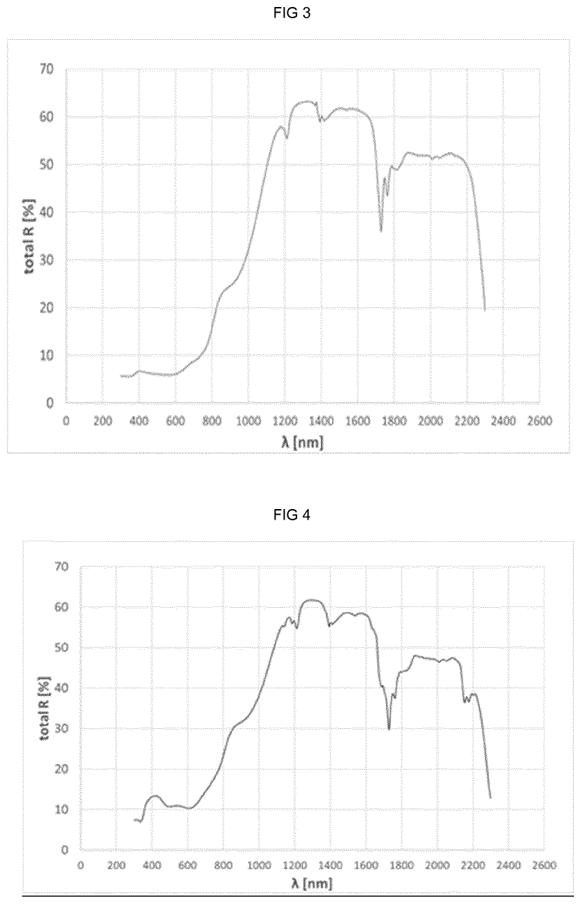

FIG. 3 is a plot of reflectivity against wavelength for the film of Example 4, an NIR-reflective, colored polymeric layer.

FIG. 4 is a plot of reflectivity against wavelength for the co-extruded film of Example 5, a multi-layer material sheet.

FIG. 5 is a plot of reflectivity against wavelength for the co-extruded film of Examples 6, 7, 8, multi-layer material sheets, and Comparative Experiment 1.

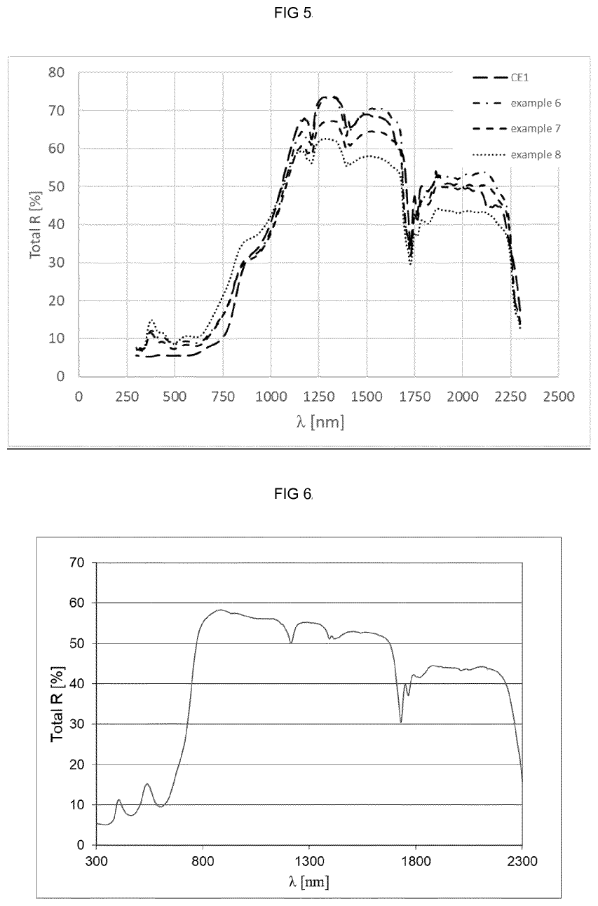

FIG. 6 is a plot of reflectivity against wavelength for the film of Example 4, an NIR-reflective, colored polymeric layer.

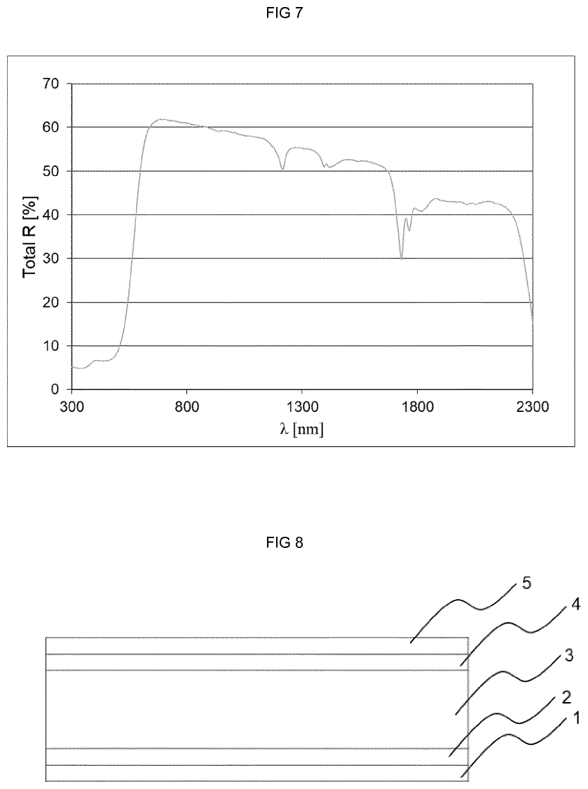

FIG. 7 is a plot of reflectivity against wavelength for the film of Example 4, an NIR-reflective, colored polymeric layer.

FIG. 8 shows an example multi-layer material sheet according to the present invention. A functional layer (1) is connected to a structure-reinforcing layer (3) through a tie-layer (2). A weather resistant layer (5) is connected to the other side of the structure-reinforcing layer (3) via a second tie layer (4).

The present invention will now be described in detail with reference to the following non-limiting examples which are by way of illustration.

### EXAMPLES

### Example 1

### Preparation of NIR-Reflective Translucent Granulate 1

Granulate of NIR-reflective translucent polymeric material was produced by addition of Iriotec® 9870 powder to a powder of a polymeric mixture of 70 wt % polyethylene and a 30 wt % polyethylene copolymer including additives into a twin-screw extruder equipped with feeders, an 18 mm screw containing elements for mixing, melting and transport of the melt, vacuum dome, atmospheric degassing and a die-plate of 1×4 mm. After the die in consecutive order a 1.5 m long water bath, an air knife and pelletizer was installed. Total concentration of Iriotec® 9870 in the compound was 3 wt % in relation to the total weight of the polymeric material. All materials were dosed on the throat. Temperatures of zone 1 is set to 200° C., the other zones were set to 230° C. Temperature of the melt measured upon exiting the die is 270° C. Extruder was set to 300 RPM and the throughput is 5 kg/hr. Vacuum was set to −0.7 bar.

### Example 2

### Preparation of NIR-Reflective Black Granulate 2

Granulate of NIR-reflective black polymeric material was produced by addition of Shepherd Black BK10G966 powder to polypropylene including additives as a powder into a twin-screw extruder equipped with feeders, an 18 mm screw containing elements for mixing, melting and transport of the melt, vacuum dome, atmospheric degassing and a die-plate of 1×4 mm. After the die in consecutive order a 1.5 m long water bath, an air knife and pelletizer was installed. Total concentration of Shepherd Black BK10G966 in the compound is 8 wt % in relation to the total weight of the polymeric material. All materials were dosed on the throat. Temperature of zone 1 was set to 200° C. the other zones were set to 230° C. Temperature of the melt measured upon exiting the die was 270° C. Extruder was set to 300RPM and the throughput was 5 kg/hr. Vacuum was set to −0.7 bar.

### Example 3

### Film Processing of the NIR-Reflective, Translucent Granulate 1

Granulate 1 (Example 1) was processed into a cast film of approximately 20 μm thickness by using a Collin flat line set-up equipped with a single screw extruder 30/25D with a 3-stage screw, feed block, flat coat die of 300×0.4 mm and a take-off device. Cylinder temperatures went from water cooled at the intake till 225° C. at the end. Connector, feed block and die temperatures were set till 225° C. Take off speed was 5 m/min. Screw speed was 15 RPM.

Total reflectivity and total transmittance of this film was measured using integrating sphere apparatus and based on ISO 13468-2 at 20 μm thickness and is shown in FIG. 1 and FIG. 2.

### Example 4

### Film Processing of the NIR-Reflective, Black Granulate 2

Granulate 2 (example 2) was processed into a cast film of approximately 150 μm thickness by using a Collin flat line set-up equipped with a single screw extruder 30/25D with a 3-stage screw, feed block, flat coat die of 300×0.4 mm and a take-off device. Cylinder temperatures went from water cooled at the intake till 225° C. at the end. Connector, feed block and die temperatures were set till 225° C. Take off speed was 3 m/min. Screw speed was 60 RPM. Total reflectivity of this film was measured using integrating sphere apparatus and based on ISO 13468-2 at 150 μm thickness and is shown in FIG. 3.

### Example 5

### NIR-Reflective Multi-Layer Backsheets

Granulates 1 and 2 were coextruded into a multi-layer cast film of 170 μm thickness by using a Collin flat film line with a multi-layer set up with 2 extruders. Extruder A was a single screw extruder 30/25D with a 3-stage screw. Extruder B was a single screw extruder 25/25D also with a 3-stage screw. It was further equipped with a feed block 2-layer set-up, a flat coat die 300×0.4 mm and a take-off device. Cylinder temperatures change from water cooled at the intake till 225° C. at the end. Connector, feed block and die temperatures were set till 225° C. Take off speed was 3 m/min. Granulate 2 was fed onto extruder A and screw speed was 60 RPM which gives a thickness of 150 μm. Granulate 1 was fed on extruder B and screw speed was 16 RPM which gives a thickness of 20 μm. Total reflectivity of this film is measured with the NIR-reflective translucent layer towards the light source using integrating sphere apparatus and based on ISO 13468-2 at 170 μm thickness and is shown in FIG. 4.

### Examples 6 to 8

The ingredients listed for each layer of each example in Table 1, below were respectively melt mixed in an extruder together with standard additives and pelletized to obtain pellets for use in the respective layers. Parts given are parts by weight, the total weight of each component being 100.

TABLE 1

| | Weather- | | | |
|---|---|---|---|---|
| Example | resistant | | Structure | Functional |
| no. | layer | Tie layer | reinforcing layer | Layer |
| Ex. 6 | 100 parts | 90 parts maleic | 92 parts | 59 parts |
| | of TiO₂ - | anhydride grafted | copolymerized | polyethylene; 27 |
| | filled | polypropylene; 10 | polypropylene; 8 | parts ethylene |
| | stabilized | parts α-olefin | parts Sicopal black | copolymer; 11 parts |
| | PA12 | block copolymer | K0095; | copolymerized |
| | | | | polypropylene; 3 |
| | | | | parts Iriotec ® 9870; |
| Ex. 7 | 100 parts | 90 parts of maleic | 92 parts | 59 parts |
| | carbon | anhydride grafted | copolymerized | polyethylene; 27 |
| | black- | polypropylene; 10 | polypropylene; 8 | parts ethylene |
| | filled | parts α-olefin | parts Sicopal black | copolymer; 11 parts |
| | stabilized | block copolymer | K0095 | copolymerized |
| | PA12 | | | polypropylene; 3 |
| | | | | parts Iriotec ® 9870; |
| Ex. 8 | 100 parts | 87 parts of maleic | 92 parts | 59 parts |
| | carbon | anhydride grafted | copolymerized | polyethylene; 27 |
| | black- | polypropylene; 10 | polypropylene; 8 | parts ethylene |
| | filled | parts α-olefin | parts Sicopal black | copolymer; 11 parts |
| | stabilized | block copolymer; | K0095 | copolymerized |
| | PA12 | 3 parts Iriotec ® | | polypropylene; 3 |
| | | 9870 | | parts Iriotec ® 9870; |

For each example, the pellets were fed to one of multiple extruders, melt-extruded at a high temperature, passed through an adapter and a die, cooled by a cooling roller and shaped into a multi-layer film having a total thickness of 300 μm. Each example had, in order, the following composition:
30 μm weather-resistant layer;
25 μm tie layer;
190 μm structure-reinforcing layer;
25 μm tie layer;
30 μm functional layer.

### Comparative Experiment 1

### High Reflective Black Backsheet

A high reflective black backsheet produced according to embodiment (3) of Examples 1 and 2 of US 2013/276876.

The total reflectivity of each of Examples 6, 7, 8 and Comparative Example 1 was measured using integrating sphere apparatus and based on ISO 13468-2, with the functional polymeric layer towards the light source. The results are shown in FIG. 5. Examples 6, 7 and especially 8 give higher total reflectance in the NIR region from 750 nm till 1000 nm. Examples 6, 7 and especially 8 give higher total reflectance in the NIR region from 750 nm till 1000 nm. This wavelength range is most relevant, since this range is above the visible spectral range for the human eye (approximately 380-740 nm) and in this range the (external) quantum efficiency for a typical silicon solar cell is relatively high (>90%).

### Example 9

### NIR-Reflective Green-Colored Polymeric Layer

A strand of NIR-reflective polymeric material was produced by addition of Shepherd Green 100650 powder to a powder of a polymeric mixture of 70 wt. % polyethylene and a 30 wt. % polyethylene copolymer including additives. The mixture was introduced into a small-scale twin-screw extruder. The total concentration of Shepherd Green 100650 in the compound was 8 wt. % in relation to the total weight of the polymeric material. The mixture was melt extruded at 175° C. and 200 rpm over 2 minutes, wherein the material is collected as a strand. A film was pressed from this strand by placing approximately 1 gram into a precut aluminum mold with dimensions 100 mm×100 mm×65 μm. Pressing was carried out using a THB400 handheld press at 175° C. for 3 minutes. Pressure was increased stepwise from 100 to 200 and finally 300 kN. Each step lasted 1 minute. After 3 minutes, the sample was cooled under pressure to room temperature. A film having a thickness of 100 μm was obtained. The total reflectivity of the film was measured using integrating sphere apparatus and based on ISO 13468-2 and is shown in the FIG. 6. A green-coloured film showing significant reflectivity above 750 nm wavelength was produced.

### Example 10

### NIR-Reflective Orange-Colored Polymeric Layer

Example 9 was repeated except that 8 wt. % Shepherd Orange 10P340 powder was used in place of 8 wt. % Shepherd Green 100650. Total reflectivity of the film was measured using integrating sphere apparatus and based on ISO 13468-2 and is shown in the FIG. 7. An orange-coloured film showing significant reflectivity above 600 nm wavelength was produced.

1. A multi-layer material sheet comprising an NIR-reflective, translucent polymeric layer having a reflectance of more than 20% of all light with a wavelength from 750 nm to 1000 nm and a transmission of more than 50% of all light with a wavelength from 380 nm to 750 nm; and an NIR-reflective, colored polymeric layer having a reflectance of more than 25% of all light with a wavelength from 1000 nm to 2100 nm.

2. A multi-layer material sheet according to claim 1, whereby the NIR-reflective, colored polymeric layer has a reflectance of less than 35% of all light with a wavelength from 380 nm to 750 nm.

3. A multi-layer material sheet according to claim 1, wherein the NIR-reflective, translucent polymeric layer and the NIR-reflective, colored polymeric layer are adjacent to each other or are separated by an adhesive layer.

4. A multi-layer material sheet according to claim 1, wherein the NIR-reflective, translucent polymeric layer comprises an inorganic near infra-red-reflective pigment.

5. A multi-layer material sheet according to claim 4, wherein the inorganic near infra-red-reflective pigment is selected from the group consisting of mica, SiO₂, TiO₂, tin oxide, ZnO, ZnSnO, aluminium-doped ZnO, indium tin oxide, antimony tin oxide, ZrO₂ and mixtures thereof.

6. A multi-layer material sheet according to claim 4, wherein the NIR-reflective, translucent polymeric layer comprises from 0.1 wt. % to 8 wt. % of the inorganic near infra-red-reflective pigment, based on the total weight of the NIR-reflective, translucent polymeric layer.

7. A multi-layer material sheet according to claim 1, 6, wherein the NIR-reflective, translucent polymeric layer has a total transmittance ≥50% as measured according to ISO13468-2.

8. A multi-layer material sheet according to claim 1, wherein the NIR-reflective, translucent polymeric layer comprises a thermoplastic polymer.

9. A multi-layer material sheet according to claim 8, wherein the thermoplastic polymer is a polyolefin or a mixture of polyolefins.

10. A multi-layer material sheet according to claim 1, wherein the NIR-reflective, colored polymeric layer comprises a thermoplastic polymer.

11. A multi-layer material sheet according to claim 10, wherein the thermoplastic polymer of the NIR-reflective, colored polymeric layer is selected from the group consisting of polyamide, polyester, rubber modified polyester, polyolefin and combinations thereof.

12. A multi-layer material sheet according to claim 1, wherein the NIR-reflective, translucent polymeric layer has a thickness of from 10 μm to 150 μm.

13. A multi-layer material sheet according to claim 1, wherein the NIR-reflective, colored polymeric layer has a thickness of from 100 μm to 400 μm.

14. A multi-layer material sheet according to claim 1, further comprising a weather-resistant layer.

15. A multi-layer material sheet comprising a NIR-reflective, translucent polymeric layer having a reflectance of more than 20% of all light with a wavelength from 750 nm to 1000 nm and a transmission of more than 50% of all light with a wavelength from 380 nm to 750 nm; and a colored polymeric layer having a reflectance of less than 35% of all light with a wavelength from 380 nm to 2100 nm.

16. A multi-layer material sheet according to claim 15 wherein the colored polymeric layer comprises carbon black.

17. A multi-layer material sheet comprising:
a) an NIR-reflective, translucent polymeric layer, which layer comprises functionalized polyethylene, polyethylene and optionally polypropylene and an NIR-reflective pigment;
b) an NIR-reflective, colored layer, which layer comprises a polyolefin, an NIR reflective pigment and a colored pigment; and
c) a weather-resistant layer.

18. A multi-layer material sheet according to claim 17, wherein:
a) the NIR-reflective, translucent polymeric layer has a thickness of from 10 to 150 μm and comprises ethylene copolymerized with methacrylate and from 0.1 to 8 wt. % of an NIR-reflective pigment comprising mica and SiO₂;
b) the NIR-reflective, colored layer has a thickness of from 100 to 400 μm and comprises polypropylene or propylene copolymerized with maleic anhydride and from 0.1 to 8 wt. % of NIR-reflective pigment which is also a colored pigment; and
c) the weather-resistant layer comprises polyamide 12 or polypropylene.

19. A backsheet suitable for use in a photovoltaic module, said backsheet comprising a multi-layer material sheet as defined in claim 1,

20. A photovoltaic module comprising a backsheet as defined in claim 19.

21. A photovoltaic module according to claim 20, comprising, in order of position from the front, sun-facing, side to the back, non-sun-facing side: a transparent top layer;
optionally a front encapsulant layer; a solar cell layer comprising one or more electrically interconnected solar cells; optionally, a back encapsulant layer; and a backsheet.
